(19) United States
(12) Patent Application Publication
(10) Pub. No.: US 2015/0228708 A1
(43) Pub. Date: Aug. 13, 2015

(54) TUNABLE POLY RESISTORS FOR HYBRID REPLACEMENT GATE TECHNOLOGY AND METHODS OF MANUFACTURING

(71) Applicant: GLOBALFOUNDRIES Inc., Grand Cayman (KY)

(72) Inventors: Andrei SIDELNICOV, Dresden (DE); Peter BAARS, Dresden (DE)

(73) Assignee: GLOBALFOUNDRIES Inc., Grand Cayman (KY)

(21) Appl. No.: 14/176,746

(22) Filed: Feb. 10, 2014

(51) Int. Cl. H01L 49/02; H01L 21/02; H01L 21/308; H01L 21/306; H01L 21/3213; H01L 29/06; H01L 21/321

(52) U.S. Cl. CPC H01L 28/20; H01L 29/0649; H01L 21/02532; H01L 21/02186; H01L 21/32115; H01L 21/30604; H01L 21/32139; H01L 21/3081

(57) ABSTRACT

A poly resistor manufacturing method which allows resistor targeting and/or tuning by process rather than by design is disclosed. Embodiments include forming a high-k dielectric on a STI layer; forming a Ti layer on the high-k dielectric; forming a dummy Si layer on the TiN layer; forming spacers at opposite sides of the high-k dielectric, TiN, and dummy Si layers; forming an ILD surrounding the spacers; removing a portion of the dummy Si layer adjacent to each spacer, down to the TiN layer, to form a metal resistor end region; filling each metal resistor end region with a pWF stack; recessing the dummy Si layer between the pWF stacks; forming a TiN hardmask over the ILD, the spacers, the pWF stacks, and the recessed dummy Si layer; forming a nWF stack over the TiN hardmask; and planarizing the nWF metal stack and the TiN hardmask down to the ILD.

### TECHNICAL FIELD

The present disclosure relates to manufacture of semiconductor devices with polysilicon (poly) resistors. The present disclosure is particularly applicable to 28 nanometer (nm) hybrid replacement metal gate (RMG) technology, and more particularly to hybrid RMG technology with dual poly removal (in which the nMOS and the pMOS are patterned separately).

### BACKGROUND

The targeting of poly resistors in conventional integration approaches is done by design and implants. For RMG technology, poly resistors consist of poly and metal parts that are not connected to the poly via silicide. Therefore, a tuning by implantation approach has no effect since the actual resistor is formed by metal below the poly layer. In addition, most of the passive devices in recent technologies have no dedicated process for independently tuning the poly resistor during product development and ramp-up phases.

In modern hybrid RMG designs, a resistor structure is used where parts of the dummy gates are not removed, but used as a poly resistor. Hybrid RMG technology refers to a special integration approach in which the high-k dielectric and the titanium nitride (TiN) cap are patterned together with the dummy gates and will not be removed during the replacement gate process. In contrast, in the full RMG approach high-k and TiN layers are deposited after removing the dummy gates. The hybrid RMG approach allows use of the TiN layer under the undoped dummy silicon as a resistor. However, the sheet resistance is defined by the design and the TiN thickness, which strongly depends on work function engineering.

A need therefore exists for methodology enabling fabrication of a poly resistor that can be targeted and/or tuned by patterning processes rather than by design, and the resulting device.

### SUMMARY

An aspect of the present disclosure is a method of fabricating a poly resistor that can be tuned by patterning processes rather than by design.

Another aspect of the present disclosure is a device including dual metal resistor layers electrically connected in parallel by resistor end regions filled with a p-type work function (pWF) metal.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming a high-k dielectric layer on a shallow trench isolation (STI) layer; forming a TiN layer on the high-k dielectric layer; forming a dummy silicon (Si) layer on the TiN layer; forming spacers at opposite sides of the high-k dielectric, TiN, and dummy Si layers; forming an interlayer dielectric (ILD) surrounding the spacers; removing a portion of the dummy Si layer adjacent to each spacer, down to the TiN layer, to form a metal resistor end region; filling each metal resistor end region with a pWF stack; recessing the dummy Si layer between the pWF stacks; forming a TiN hardmask layer over the ILD layer, the spacers, the pWF stacks, and the recessed dummy Si layer; forming a n-type work function (nWF) stack over the TiN hardmask layer; and planarizing the nWF metal stack and the TiN hardmask layer down to the ILD layer.

Aspects of the present disclosure include forming the high-k dielectric layer to a thickness of 10 angstroms (Å) to 30 Å. Other aspects include forming the TiN layer to a thickness of 10 Å to 40 Å. Further aspects include forming the dummy Si layer to a thickness of 500 Å to 850 Å. Another aspect includes removing the portion of the dummy Si layer adjacent to each spacer by etching. Additional aspects include removing a 180 nm to 300 nm wide portion of the dummy Si layer. Other aspects include forming the pWF stacks of tantalum nitride (TaN), TiN, Ti, and aluminum (Al). Further aspects include recessing the dummy Si layer by etching. Another aspect includes recessing the dummy Si layer to a depth of 30 Å to 200 Å. Additional aspects include forming the TiN hardmask to a thickness of 40 Å to 100 Å. Other aspects include forming the nWF stack of TaN, TiN, and titanium aluminum (TiAl). Further aspects include forming the dummy Si layer by forming a first layer of Si and a second layer of silicon germanium (SiGe) on the first Si layer. Another aspect includes forming the SiGe layer to a thickness of 30 Å to 200 Å. Additional aspects include removing the portion of the dummy Si layer adjacent to each spacer by etching the SiGe and Si layers. Other aspects include recessing the dummy Si layer by recessing the SiGe layer by etching selective to the Si layer.

Another aspect of the present disclosure is a device including: an STI layer; a high-k dielectric layer formed on the STI layer; a TiN layer formed on the high-k dielectric layer; a dummy Si layer formed on the TiN layer; spacers at opposite sides of the high-k, TiN, and dummy Si layers; an ILD surrounding the spacers; pWF stacks formed on the TiN layer, between the spacers and the dummy Si layer, wherein the dummy Si layer is recessed below an upper surface of the pWF stacks; a TiN hardmask formed over the ILD, the spacers, the pWF stacks, and the recessed dummy Si layer; and an nWF stack formed over the TiN hardmask.

Aspects of the device include the TiN hardmask being formed to a thickness of 40 Å to 100 Å. Other aspects include a final thickness of the nWF stack being 0 Å to 100 Å. Further aspects include the pWF stacks including TaN, TiN, Ti, and Al and the nWF stack including TaN, TiN, and TiAl.

Another aspect of the present disclosure is a method including: forming a high-k dielectric layer on a STI layer to a thickness of 10 Å to 30 Å; forming a TiN layer on the high-k dielectric layer to a thickness of 10 Å to 40 Å; forming a dummy Si layer on the TiN layer to a thickness of 500 Å to 850 Å; forming a dummy SiGe layer on the dummy Si layer to a thickness of 30 Å to 200 Å; forming spacers at opposite sides of the high-k dielectric, TiN, and dummy Si layers; forming an ILD surrounding the spacers; removing a 180 nm to 300 nm wide portion of the dummy SiGe and dummy Si layers adjacent to each spacer, down to the TiN layer, to form a metal resistor end region; filling each metal resistor end region with a pWF stack; etching the dummy SiGe layer selective to the dummy Si layer; forming a TiN hardmask layer over the ILD layer, the spacers, the pWF stacks, and the dummy Si layer to a thickness of 500 Å to 850 Å; forming a nWF stack over the TiN hardmask to a thickness of 900 Å to 1600 Å; and planarizing the nWF metal stack down to the ILD layer.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A through 4A and 5 through 7 schematically illustrate sequential steps of a method of fabricating a tunable poly resistor using a uniform dummy Si layer, in accordance with an exemplary embodiment; and

FIGS. 1B through 4B and 5 through 7 schematically illustrate sequential steps of a method of fabricating a tunable poly resistor using a dummy Si/SiGe bi-layer, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of an inability to tune poly resistors by patterning rather than by design attendant upon forming poly resistors for RMG technologies. By implementing upper and lower metal resistor layers, which are electrically connected in parallel by resistor end regions filled with pWF metal, the thickness of the upper metal resistor layer can be adjusted to tune the resistance of the poly resistor.

Methodology in accordance with embodiments of the present disclosure includes forming a high-k dielectric layer on an STI layer. A TiN layer is formed on the high-k dielectric layer. A dummy Si layer is formed on the TiN layer. Spacers are formed at opposite sides of the high-k dielectric, TiN, and dummy Si layers. An ILD is formed surrounding the spacers. A portion of the dummy Si layer adjacent to each spacer is removed, down to the TiN layer, to form a metal resistor end region. Each metal resistor end region is filled with a pWF stack. The dummy Si layer is recessed between the pWF stacks. A TiN hardmask layer is formed over the ILD layer, the spacers, the pWF stacks, and the recessed dummy Si layer. An nWF stack is formed over the TiN hardmask layer. The nWF metal stack and the TiN hardmask layer are planarized down to the ILD layer.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

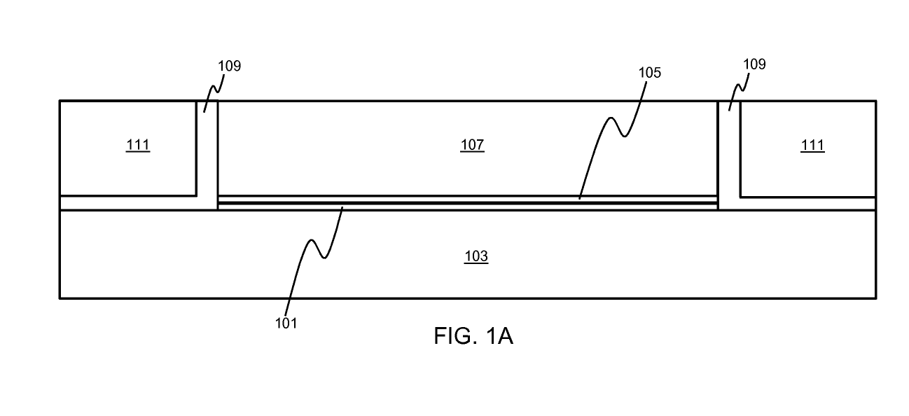

FIGS. 1A through 4A and 5 through 7 schematically illustrate sequential steps of a method of forming a tunable poly resistor using a uniform dummy Si layer, in accordance with an exemplary embodiment. Adverting to FIG. 1A, a high-k dielectric layer 101 is formed on an STI layer 103, for example to a thickness of 10 Å to 30 Å. Next, a TiN layer 105 is formed on the high-k dielectric layer 101, e.g., to a thickness of 10 Å to 40 Å. A dummy Si layer 107 is then formed on the TiN layer 105. The dummy Si layer 107 may be formed to a thickness of 500 Å to 850 Å. Thereafter, spacers 109, which may be L-shaped are formed on opposite sides of the high-k dielectric layer 101, the TiN layer 105, and the dummy Si layer 107. An ILD 111 is then formed surrounding the spacers 109.

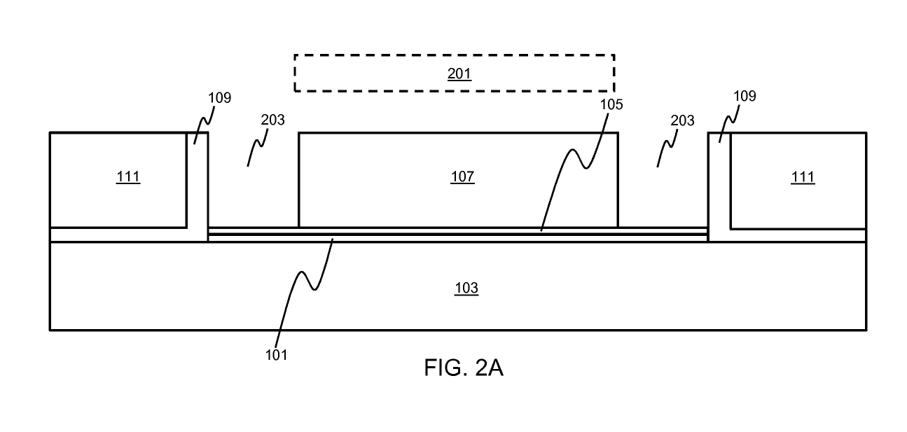

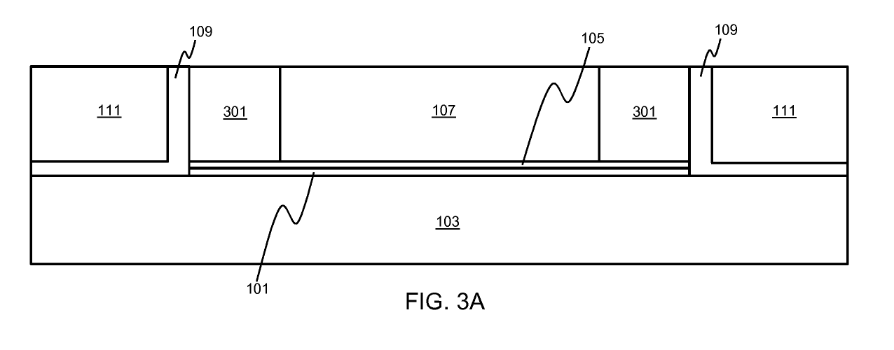

Next, as illustrated in FIG. 2A, using a n-type gate blocking mask (NG) 201 over a center portion of the dummy Si layer 107, a portion of the dummy Si layer 107 adjacent to each spacer 109 is removed by etching down to the TiN layer 105. For example, the portion of the dummy Si layer 107 is removed by reactive ion etching (RIE). Alternatively, the portion of the dummy Si layer 107 may be removed by RIE and wet etching (if needed). The removed portions may be 180 nm to 300 nm wide and form metal resistor end regions 203. The metal resistor end regions 203 are then filled with a pWF stack 301, e.g., TaN, TiN, Ti, and Al, as depicted in FIG. 3A.

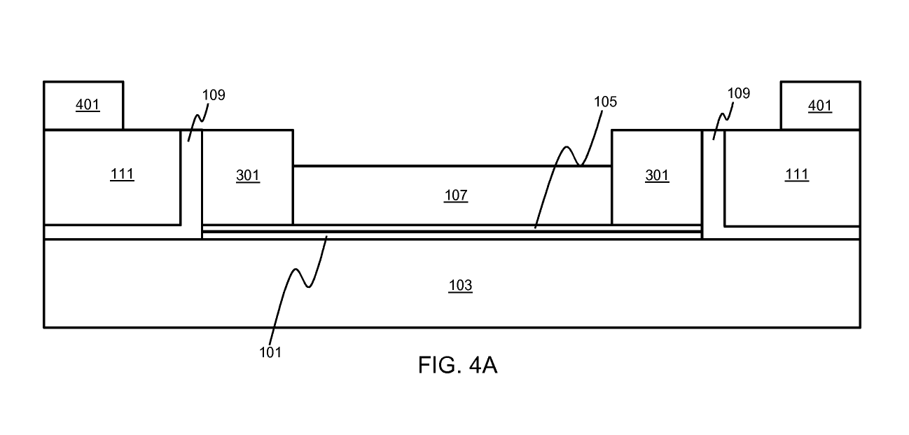

Adverting to FIG. 4A, the remaining dummy Si layer 107 is recessed between the pWF stacks 301 to a depth of 30 Å to 200 Å by etching using the poly resistor masks 401. Again, the remaining dummy Si layer 107 may be recessed by RIE. Alternatively, the remaining dummy Si layer 107 may be recessed by RIE and wet etching (if needed). In particular, the depth of the recess of the dummy Si layer 107 defines the sheet resistance of the poly resistor structure and enables fine tuning of the resistance.

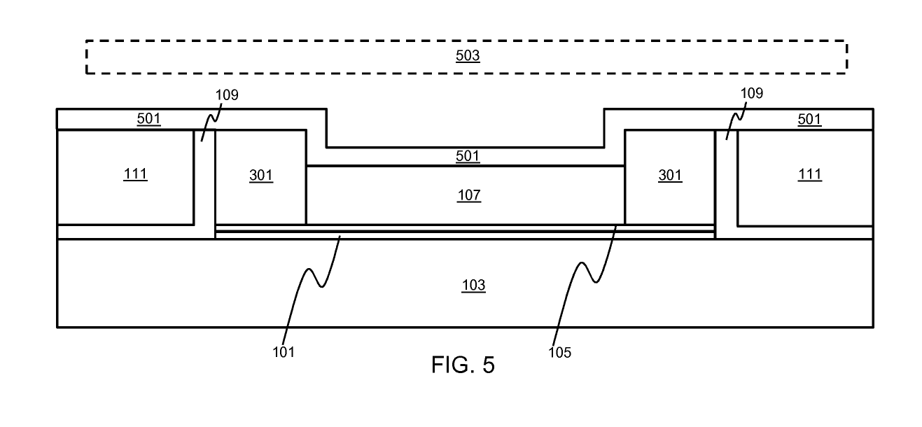

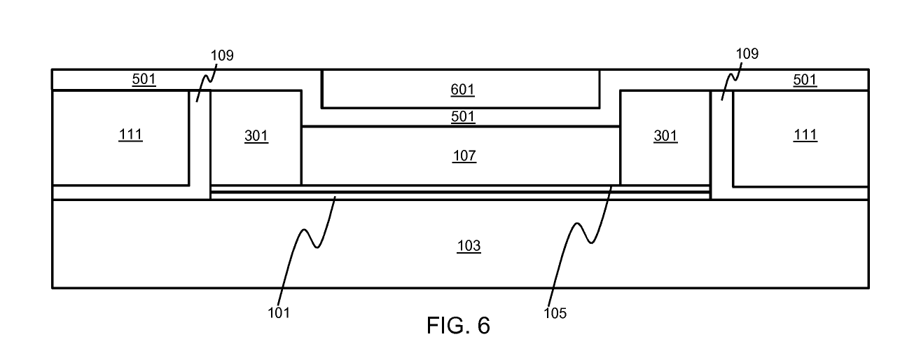

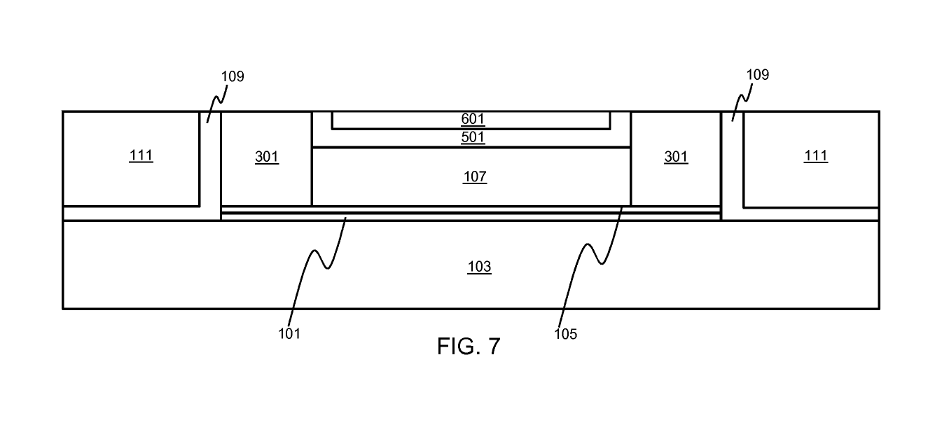

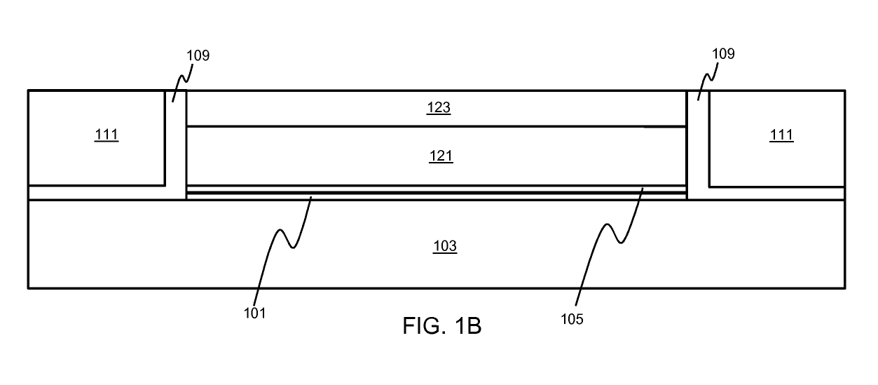

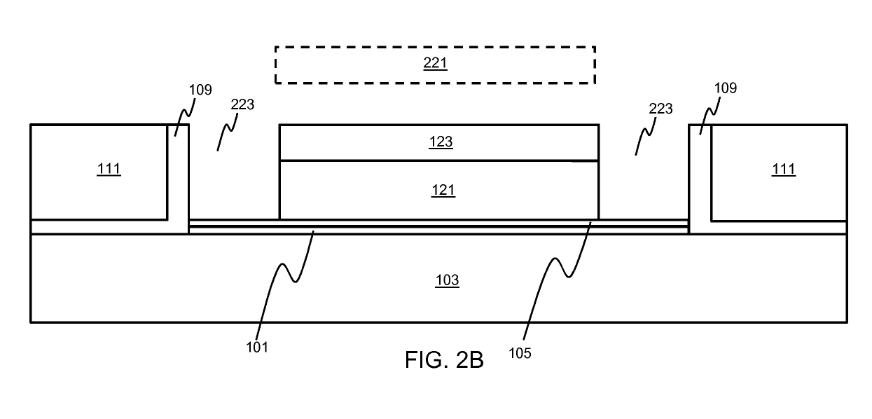

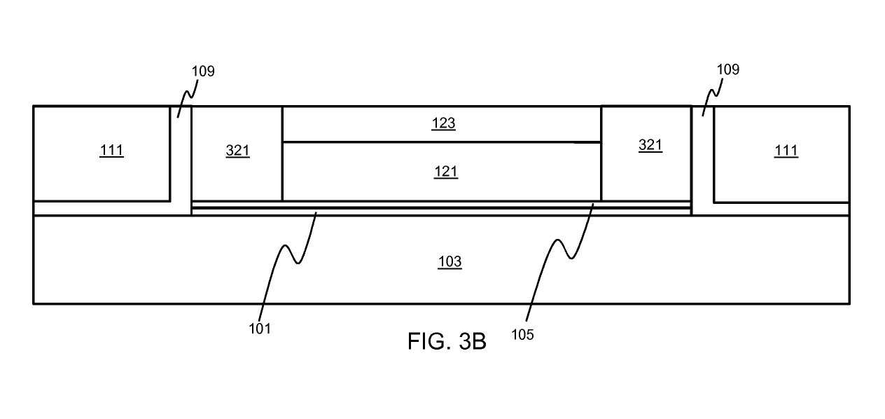

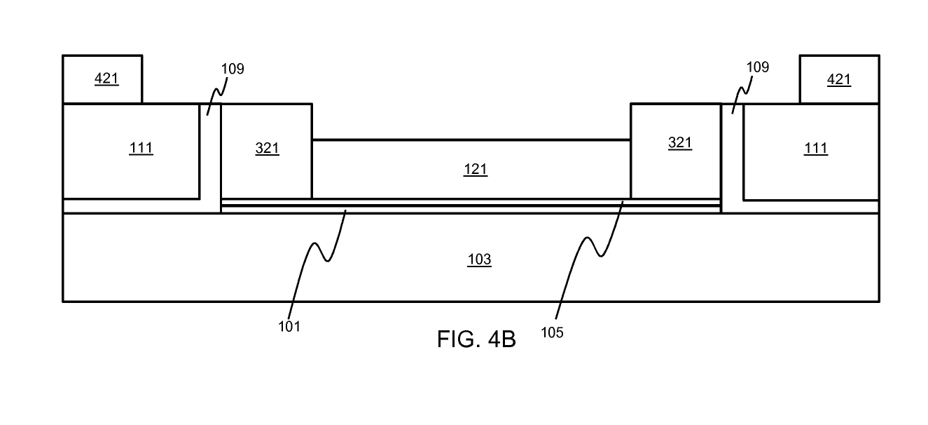

After the recess is formed, as shown in FIG. 5, resistor masks 401 are stripped, and a TiN hardmask 501 is formed on the ILD 111, the spacers 109, the pWF stacks 301, and the dummy Si layer 107, for example to a thickness of 40 Å to 100 Å. The TiN hardmask 501 is the hardmask used in the dual poly removal approach. The resistor is then covered with a p-type gate blocking mask (PG) 503, the PG is formed by lithography, and the resist 503 is then stripped. Adverting to FIG. 6, a nWF metal stack 601, e.g., TaN, TiN, and TiAl, is formed over the TiN hardmask 501, for example to a thickness of 900 Å to 1600 Å. Thereafter, the nWF metal stack 601 and the TiN hardmask 501 are planarized, e.g., by CMP, down to the ILD layer 111, as depicted in FIG. 7. In the resulting device, the TiN hardmask 501 and the nWF metal stack 601 are electrically connected in parallel to the TiN layer 105 by the pWF stacks 301. Accordingly, the resistance of the poly resistor structure may be changed and/or tuned by adjusting the recess depth of the dummy Si layer 107.

Alternatively, FIGS. 1B through 4B and 5 through 7 schematically illustrate sequential steps of a method of forming a tunable poly resistor using a dummy Si/SiGe bi-layer, in accordance with an exemplary embodiment. The process begins the same as in FIG. 1A, except for the formation of the dummy Si layer 107. In particular, rather than forming a dummy Si layer 107 as depicted in FIG. 1A, a dummy Si layer may be formed of a Si layer 121 on the TiN layer 105, and an SiGe layer 123 on the Si layer 121, e.g., having a thickness of 30 Å to 200 Å, for a total thickness of 500 Å to 850 Å, for example, as depicted in FIG. 1B. Similar to FIG. 2A, using an NG mask 221 over a center portion of the Si 121 layer and the SiGe layer 123, a portion of Si 121 and SiGe 123 near each spacer is removed down to the TiN layer 105. The portions of Si 121 and SiGe 123 may be removed by etching to a width of 180 nm to 300 nm to form metal resistor end regions 223. In particular, the portions of Si 121 and SiGe 123 may be removed by RIE. Alternatively, the portions of Si 121 and SiGe 123 may be removed by RIE and wet etching (if needed). Thereafter, similar to FIG. 3A, the metal resistor end regions 223 are filled with a pWF stack 321, e.g., TaN, TiN, Ti, and Al, as depicted in FIG. 3B.

Adverting to FIG. 4B, the SiGe layer 123 is recessed by etching selective to the Si layer 121 using poly resistor masks 421, similar to FIG. 4A. Again, the SiGe layer 123 may be recessed by RIE. Alternatively, the SiGe layer 123 may be recessed by RIE and wet etching (if needed). The recess depth of the SiGe layer 123 will define the sheet resistance of the poly resistor structure and therefore enables fine tuning of the resistance. Once the SiGe layer 123 is etched and the poly resistor masks 421 are stripped, the steps described with respect to FIGS. 5 through 7 are performed.

The embodiments of the present disclosure can achieve several technical effects including “in-depth” resistor tuning without changing the device foot-print area or using implant processes, full compatibility with hybrid dual poly removal RMG technology, and self-adjusted formation of the resistor body with no overlay issues. Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure enjoys industrial applicability in various types of integrated circuits including resistors, particularly in the 28 nm technology node.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming a high-k dielectric layer on a shallow trench isolation (STI) layer;
forming a titanium nitride (TiN) layer on the high-k dielectric layer;
forming a dummy silicon (Si) layer on the TiN layer;
forming spacers at opposite sides of the high-k dielectric, TiN, and dummy Si layers;
forming an interlayer dielectric (ILD) surrounding the spacers;
removing a portion of the dummy Si layer adjacent to each spacer, down to the TiN layer, to form a metal resistor end region;
filling each metal resistor end region with a p-type work function (pWF) stack;
recessing the dummy Si layer between the pWF stacks;
forming a TiN hardmask layer over the ILD layer, the spacers, the pWF stacks, and the recessed dummy Si layer;
forming a n-type work function (nWF) stack over the TiN hardmask layer; and
planarizing the nWF metal stack and TiN hardmask layer down to the ILD layer.

2. The method according to claim 1, comprising forming the high-k dielectric layer to a thickness of 10 angstroms (Å) to 30 Å.

3. The method according to claim 1, comprising forming the TiN layer to a thickness of 10 Å to 40 Å.

4. The method according to claim 1, comprising forming the dummy Si layer to a thickness of 500 Å to 850 Å.

5. The method according to claim 1, comprising removing the portion of the dummy Si layer adjacent to each spacer by etching.

6. The method according to claim 5, comprising removing a 180 nanometer (nm) to 300 nm wide portion of the dummy Si layer.

7. The method according to claim 1, comprising forming the pWF stacks of tantalum nitride (TaN), TiN, Ti, and aluminum (Al).

8. The method according to claim 1, comprising recessing the dummy Si layer by etching.

9. The method according to claim 7, comprising recessing the dummy Si layer to a depth of 30 Å to 200 Å.

10. The method according to claim 1, comprising forming the TiN hardmask to a thickness of 40 Å to 100 Å.

11. The method according to claim 1, comprising forming the nWF stack of TaN, TiN, and titanium aluminum (TiAl).

12. The method according to claim 1, comprising forming the dummy Si layer by forming a first layer of Si and a second layer of silicon germanium (SiGe) on the first Si layer.

13. The method according to claim 12, comprising forming the SiGe layer to a thickness of 30 Å to 200 Å.

14. The method according to claim 12, comprising removing the portion of the dummy Si layer by etching the SiGe and Si layers.

15. The method according to claim 12, comprising recessing the dummy Si layer by etching the SiGe selective to the Si layer.

16. A device comprising:
a shallow trench isolation (STI) layer;
a high-k dielectric layer formed on the STI layer;
a titanium nitride (TiN) layer formed on the high-k dielectric layer;
a dummy silicon (Si) layer formed on the TiN layer;
spacers at opposite sides of the high-k, TiN, and dummy Si layers;
an interlayer dielectric (ILD) surrounding the spacers;
p-type work function (pWF) stacks formed on the TiN layer, between the spacers and the dummy Si layer, wherein the dummy Si layer is recessed below an upper surface of the pWF stacks;
a TiN hardmask formed over the ILD, the spacers, the pWF stacks, and the recessed dummy Si layer; and
an n-type workfunction (nWF) stack formed over the TiN hardmask.

17. The device according to claim 16, wherein the TiN hardmask is formed to a thickness of 40 Å to 100 Å.

18. The device according to claim 15, wherein a final thickness of the nWF stack is 0 Å to 100 Å.

19. The device according to claim 15, wherein the pWF stacks include tantalum nitride (TaN), TiN, Ti, and aluminum (Al) and the nWF stack includes TaN, TiN, and titanium aluminum (TiAl).

20. A method comprising:
forming a high-k dielectric layer on a shallow trench isolation (STI) layer to a thickness of 10 Å to 30 Å;
forming a titanium nitride (TiN) layer on the high-k dielectric layer to a thickness of 10 Å to 40 Å;
forming a dummy silicon (Si) layer on the TiN layer to a thickness of 500 Å to 850 Å;
forming a dummy silicon germanium (SiGe) layer on the dummy Si layer to a thickness of 30 Å to 200 Å;
forming spacers at opposite sides of the high-k dielectric, TiN, and dummy Si layers;
forming an interlayer dielectric (ILD) surrounding the spacers;
removing a 180 nanometer (nm) to 300 nm wide portion of the dummy SiGe and dummy Si layers adjacent to each spacer, down to the TiN layer, by etching to form metal resistor end regions;
filling each metal resistor end region with a p-type work function (pWF) stack;
partially etching the dummy SiGe layer selective to the dummy Si layer;
forming a TiN hardmask layer over the ILD layer, the spacers, the pWF stacks, and the dummy Si layer to a thickness of 40 Å to 100 Å;
forming a n-type workfunction (nWF) stack over the TiN hardmask to a thickness of 900 Å to 1600 Å; and
planarizing the nWF metal stack and the TiN hardmask layer down to the ILD layer.
